(19) United States
(12) Patent Application Publication
(10) Pub. No.: US 2008/0048165 A1
(43) Pub. Date: Feb. 28, 2008

(54) VARIABLE RESISTANCE ELEMENT AND RESISTANCE VARIABLE TYPE MEMORY DEVICE

(75) Inventor: Hiromu MIYAZAWA, Azumino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/781,315

(22) Filed: Jul. 23, 2007

(30) Foreign Application Priority Data
Jul. 24, 2006 (JP) 2006-200638

(51) Int. Cl. H01L 45/00

(52) U.S. Cl. 257/2; 257/E45.002

(57) ABSTRACT

A variable resistance element includes: a first electrode; a resistance layer formed on the first electrode; and a second electrode formed on the resistance layer, wherein the resistance layer is composed of transition metal oxide having oxygen defects.

The entire disclosure of Japanese Patent Application No. 2006-200638, filed Jul. 24, 2006 is expressly incorporated by reference herein.

### BACKGROUND

1. Technical Field

The present invention relates to a variable resistance element and a resistance variable type memory device using the variable resistance element.

2. Related Art

RRAM (resistance random access memory) is attracting attention as a nonvolatile memory, which is capable of achieving higher speed operation, higher integration and lower power consumption. RRAM uses the phenomenon in which, upon application of a pulse voltage to a film of metal oxide, the resistance of the film generally, reversibly changes. In other words, RRAM having a variable resistance element can retain data in a non-volatile manner by setting a resistance value of the variable resistance element with a polarity or a voltage of a pulse voltage to be applied. As a material of the resistance layer composing such RRAM, for example, an oxide including manganese is described in Japanese Laid-open Patent Application JP-A-8-133894.

### SUMMARY

In accordance with an advantage of some aspects of the invention, there are provided a novel variable resistance element that is applicable to a resistance variable type memory device (also referred to as a resistance random access memory (RRAM)) and a resistance variable type memory device using the variable resistance element.

A variable resistance element in accordance with an embodiment of the invention includes a first electrode, a resistance layer formed on the first electrode, and a second electrode formed on the resistance layer, wherein the resistance layer is composed of transition metal oxide having oxygen defects.

According to the variable resistance element in accordance with the present embodiment, the transition metal oxide having oxygen defects is used as the material of the resistance layer, whereby the resistance of the resistance layer reversibly changes upon application of a pulse voltage and therefore the resistance layer has a switching function. The variable resistance element is applicable to a resistance variable type memory device such as a RRAM.

In the variable resistance element in accordance with an aspect of the present embodiment, the transition metal oxide having oxygen defects may be a transition metal oxide expressed by YₓZr₁₋ₓ O₂ (0<x≦0.3).

A resistance variable type memory device in accordance with an embodiment of the invention includes the variable resistance element described above.

### BRIEF DESCRIPTION OF THE DRAWINGS

FIG. 1 is a schematic cross-sectional view of a variable resistance element in accordance with an embodiment of the invention.

FIG. 2 is a schematic cross-sectional view of a resistance variable type memory device in accordance with an embodiment of the invention.

### DESCRIPTION OF EXEMPLARY EMBODIMENTS

Preferred embodiments of the invention are described below with reference to the accompanying drawings.

1. Variable Resistance Element

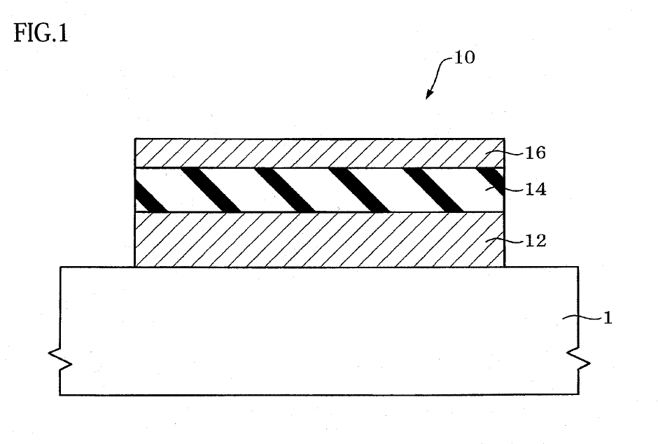

FIG. 1 is a schematic cross-sectional view of a variable resistance element 10 in accordance with an embodiment of the invention.

The variable resistance element 10 is formed on a base substrate 1. The variable resistance element 10 includes a first electrode 12 formed on the base substrate 1, a resistance layer 14 formed on the first electrode 12, and a second electrode 16 formed on the resistance layer 14.

As the base substrate 1, different substrates may be used depending on devices to which the variable resistance element 10 of the present embodiment is applied. When the variable resistance element 10 of the present embodiment is applied to a RRAM, a semiconductor substrate with MOS transistors or the like formed thereon may be used as the base substrate 1, as described below.

As the material of the first electrode 12 composing the variable resistance element 10, platinum group metal such as Pt, Ir, Ru or the like, an alloy containing platinum group metal, conductive oxide composed of oxide of platinum group metal such as Ir or Ru, or conductive oxide, such as, SRO (SrRuO₃), LSCO ((LaSr)CoO₃) can be enumerated. As the material of the second electrode 16, a material similar to that of the first electrode 12 can be used.

The resistance layer 14 is composed of transition metal oxide having oxygen defects.

It is noted that the transition metal oxide having oxygen defects may be formed by replacing a portion of the transition metal within crystals with a transition metal element having a smaller valence. For example, Y³⁺ is an example with respect to Zr⁴⁺. In other words, when the average valence of a transition metal site becomes smaller, oxygen atoms vacate because of the principle of charge neutralization, such that oxygen defects automatically occur. In this instance, the system is stable as its dielectric property is maintained.

In the present embodiment, as the transition metal oxide having oxygen defects, transition metal oxide expressed by YSZ:YₓZr₁₋ₓ O₂ (0<x≦0.3) may be used. YSZ is characterized in that a thin film of stable film thickness and specific resistance can be provided, and is therefore suitable as a resistance layer. Also, the composition ratio x of yttrium (Y) may preferably be 0<x≦0.3, and more preferably 0.03≦x≦0.15. The composition ratio of yttrium is desirably within this range, because a high rate of resistance change can be obtained.

In the variable resistance element 10 in accordance with the present embodiment, it is assumed that the resistance is reversibly changes due to the following reason. When oxygen defects within the crystal move closer to the electrode by an external voltage applied, the band offset near the interface of the electrode changes, and therefore the electrical resistance changes. For example, oxygen defects within the transition metal oxide in effect act as positive ions, and move toward a negative electrode. On the other hand, oxygen atoms themselves in effect act as negative ions, and move toward a positive electrode. There is a threshold voltage V₀ for the external voltage for moving the oxygen defects and the oxygen atoms, and the oxygen defects and the oxygen atoms move toward the corresponding electrodes, respectively, when the external voltage exceeding V₀ is applied. Signal information is recorded with a voltage value V_{W} that is greater than the threshold voltage V₀. Oxygen defects and oxygen atoms do not move when the external voltage is below the threshold voltage V₀. The resistance value is measured in this voltage range, and the voltage value V_{R} corresponds to a read-out voltage of the signal information. When a voltage in a reverse direction −V_{E} is applied, the accumulation of oxygen defects accumulated on one of the electrodes is cancelled, and the recorded information is reset. However, V_{E}>V₀ may be preferred.

The variable resistance element 10 in accordance with the present embodiment may be manufactured by, for example, a method as follows.

A conductive layer for a first electrode 12 is formed on a base substrate 1 by a sputter method. Then, a layer of transition metal oxide having oxygen defects is formed on the conductive layer. The layer of transition metal oxide may be formed by a sputter method or a sol-gel method. For example, according to the sputter method, the layer of transition metal oxide is formed in an oxygen atmosphere, using a target that provides a desired composition ratio. Also, when the sol-gel method is applied, a solution is prepared by mixing raw material solutions to have a desired composition ratio, the solution is coated on the base substrate 1, and then a heat treatment applied to the solution, whereby the layer of transition metal oxide can be formed.

Then, a conductive layer for a second electrode 16 is formed on the layer of transition metal oxide by a sputter method. Then, using known lithography and etching methods, the second electrode 16, the resistance layer 14 and the first electrode 12 are patterned.

The variable resistance element 10 in accordance with the present embodiment is characterized in that it can provide a high rate of resistance change. The variable resistance element 10 in accordance with the present embodiment, as having such a characteristic, can be favorably applied to a resistance change type memory device such as a RRAM.

The resistance value may be measured by a measurement method as follows. Application voltages are applied to the upper electrode 16 of the variable resistance element 10 as voltage pulses from a pulse generator, whereby initialization, recording and erasing of a signal are conducted. The resistance value is obtained by measuring I-V characteristics by a parameter analyzer. First, an initialization pulse voltage that changes between +V_{I} and −V_{I}, for example, with a pulse width of 100 nsec and a duty ratio of 50% is applied to the variable resistance element, thereby initializing the signal. Then, a resistance value before recording a signal is measured with a DC voltage V_{R}. Next, a pulse voltage V_{W} in a forward direction is applied to record a signal. Then, a resistance value after recording the signal is measured with a DC voltage V_{R}. Finally, a pulse voltage −V_{E} in a reverse direction is applied to the variable resistance element 10, thereby erasing the signal. Examples of the voltages may be as follows. The signal initialization voltage V_{I} is 4.0 V, the signal writing voltage V_{W} is 3.0 V, the signal read-out voltage V_{R} is 0.8 V, and the signal erasing voltage V_{E} is −3.0 V. Also, reference voltages at the time of signal writing and erasing are 0 V, and their voltage pulse shapes both have a pulse with of 50 nsec and a duty ratio of 50%, applied for 1 μsec. It is noted that the signal can be initialized in 1 sec. The rate of resistance change is obtained by the following formula.

Rate of resistance change=((resistance value after signal recording)−(resistance value upon signal initialization))/(resistance value upon signal initialization)×100

Next, experimental examples that use YSZ as a resistance layer 14 are described.

The experimental examples demonstrate that the resistance of the resistance layer changes depending on the ratio of yttrium in YSZ. As the experimental samples, the following elements were used. The element had a base substrate 1 formed from a silicon substrate having a silicon oxide layer on its surface, and a variable resistance element 10 formed on the base substrate 1. The variable resistance element 10 had a first electrode (lower electrode) 12 composed of platinum having a film thickness of 200 nm, a resistance layer 14 composed of YₓZr₁₋ₓ O₂ having a film thickness of 50 nm, and a second electrode (upper electrode) 16 composed of platinum having a film thickness of 100 nm. The films were formed by a sputter method. More concretely, the first electrode and the second electrode were formed by DC sputtering at 150 W. Also, the variable resistance element was formed by RF sputtering at 200 W. The sputtering gas was argon gas, and its gas pressure was 2×10⁻³ Torr. The yttrium composition ratio (x) in the composition of the resistance layer 12 was changed to form plural samples, and the resistance value of each of the samples was measured. The results are shown in Table 1 below.

TABLE 1

| Sample | X in Yₓ Zr₁₋ₓ O₂ | Rate of resistance change (%) |
|---|---|---|
| 1 | 0 | 5 |
| 2 | 2 | 80 |
| 3 | 3 | 130 |
| 4 | 6 | 190 |
| 5 | 10 | 230 |
| 6 | 15 | 210 |
| 7 | 20 | 90 |
| 8 | 25 | 70 |
| 9 | 30 | 50 |
| 10 | 35 | 10 |

It is confirmed from Table 1 that the composition ratio x of yttrium (Y) may preferably be 0<x≦0.3, and more preferably 0.03≦x≦0.15.

2. Resistance Variable Type Memory Device

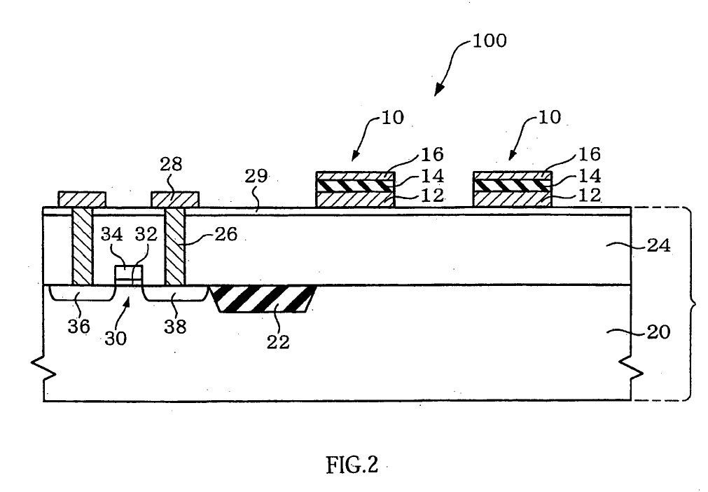

Next, a resistance variable type memory device using the variable resistance element 10 in accordance with the present embodiment is described. FIG. 2 is a schematic cross-sectional view of a resistance variable type memory device 100.

The resistance variable type memory device 100 includes a semiconductor substrate (silicon substrate) 20, an interlayer dielectric layer 24 formed on the semiconductor substrate 20, and variable resistance elements 10 formed above the interlayer dielectric layer 24. The variable resistance elements 10 are arranged in plurality to form a memory cell array.

A circuit and a peripheral circuit for driving at least the variable resistance elements 10 are formed on the semiconductor substrate 20. For example, an element isolation region 22 and a circuit element such as a MOS transistor 30 are formed on the semiconductor substrate 20. The MOS transistor 30 may be an ordinary MOS transistor having a gate dielectric layer 32, a gate electrode 34 and impurity layers 36 and 38 defining source/drain regions. The interlayer dielectric layer 24 may have an ordinary structure, and may be formed from a silicon oxide layer. Contact sections (plugs) 26 that are connected to the impurity layers 36 and 38 are formed in the interlayer dielectric layer 24. Wiring layers 28 are formed on the contact sections 26. A dielectric layer 29 that may have oxygen barrier property, hydrogen barrier property or adhesion property is formed on the interlayer dielectric layer 24. As the dielectric layer 29, titanium oxide may be used. The devices such as the MOS transistor 30 can be formed by a known semiconductor manufacturing technique.

A plurality of variable resistance elements 10 in accordance with the present embodiment are formed in a memory cell region on the dielectric layer 28. The variable resistance element 10 is described above in detail, and therefore its detailed description is not repeated. In accordance with the present embodiment, the base substrate 1 shown in FIG. 1 includes the semiconductor substrate 20, the interlayer dielectric layer 24, the dielectric layer 29 and the MOS transistor 30 formed in these layers.

According to the resistance variable type memory device 100 in accordance with the present embodiment, signals (information) can be recorded (written), read out, and erased through applying voltages to the variable resistance element 10 and measuring its resistance values by the method described above.

The invention is not limited to the embodiments described above, and many modifications can be made. For example, the invention may include compositions that are substantially the same as the compositions described in the embodiments (for example, a composition with the same function, method and result, or a composition with the same object and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A variable resistance element comprising:
a first electrode;
a resistance layer formed on the first electrode; and
a second electrode formed on the resistance layer,
wherein the resistance layer is composed of transition metal oxide having oxygen defects.

2. A variable resistance element according to claim 1, wherein the transition metal oxide having oxygen defects is a transition metal oxide expressed by YₓZr₁₋ₓ O₂ (0<x≦0.3).

3. A resistance variable type memory device comprising the variable resistance element recited in claim 1.
